(19) United States
(12) Patent Application Publication
(10) Pub. No.: US 2025/0162453 A1
(43) Pub. Date: May 22, 2025

(54) IN-SITU EIS

(71) Applicant: VOLVO TRUCK CORPORATION, Göteborg (SE)

(72) Inventor: Emil Lidström, Torslanda (SE)

(73) Assignee: VOLVO TRUCK CORPORATION, Göteborg (SE)

(21) Appl. No.: 18/951,155

(22) Filed: Nov. 18, 2024

(30) Foreign Application Priority Data
Nov. 22, 2023 (EP) 23211418.1

(51) Int. Cl. B60L 58/16; B60L 58/12; B60R 16/023

(52) U.S. Cl. CPC B60L 58/16; B60L 58/12; B60R 16/0231; B60L 2200/18; B60L 2200/36; B60L 2200/40; B60L 2240/547; B60L 2240/549

(57) ABSTRACT

A computer system comprising processing circuitry is presented. The processing circuitry is configured to, during control, by the processing circuitry, of an electrical connection between a battery pack and a traction system of a vehicle at a first switching frequency of a set of predetermined switching frequencies, synchronously obtain a first cell voltage and a first cell current of a battery cell of the battery pack; and provide the first cell voltage, the first cell current and the first switching frequency for diagnostic of the battery cell.

### TECHNICAL FIELD

The disclosure relates generally to diagnostics of battery cells. In particular aspects, the disclosure relates to in-situ diagnostics of battery cells by EIS. The disclosure can be applied to heavy-duty vehicles, such as trucks, buses, nautical vehicles and construction equipment, among other vehicle types. Although the disclosure may be described with respect to a particular vehicle, the disclosure is not restricted to any particular vehicle.

### BACKGROUND

Batteries are used in numerous applications, from simple devices as flashlights to advanced power systems for vehicles. Batteries generally have a limited lifetime that depends on their usage and several techniques exist to estimate internal data of a battery.

The internal data may describe a state of charge (SOC), a state of health (SOH) or other data used to diagnose the battery. Correct and accurate estimation of internal data is important in order to enable efficient and healthy operation of the battery.

### SUMMARY

According to a first aspect of the disclosure, a computer system comprising processing circuitry is presented. The processing circuitry is configured to during control, by the processing circuitry, of an electrical connection between a battery pack and a traction system of a vehicle at a first switching frequency of a set of predetermined switching frequencies, synchronously obtain a first cell voltage and a first cell current of a battery cell of the battery pack. The processing circuitry is further configured to provide the first cell voltage, the first cell current and the first switching frequency for diagnostic of the battery cell. A technical benefit may include being able to provide in-situ, i.e. during operation, EIS data from a battery pack or battery cell. This enables improved diagnostic capabilities, increased lifetime of batteries, better estimating of SOC, SOH etc. A further technical benefit may include enabling obtaining of EIS data without requirement for specialized hardware, EIS data may be provided utilizing hardware generally present at a vehicle.

Optionally in some examples, including in at least one preferred example, the processing circuitry is further configured to: during control, by the processing circuitry, of an electrical connection between a battery pack and a traction system of a vehicle at each additional switching frequency of the set of predetermined switching frequencies, for each additional switching frequency, synchronously obtain an additional cell voltage and an additional cell current of a battery cell of the battery pack. The processing circuitry is further configured to provide the additional cell voltages, the additional cell currents and their associated additional switching frequencies for diagnostic of the battery cell. A technical benefit may include providing the EIS data across a spectrum of frequencies, i.e. and EIS spectrum which enables further improved diagnostic capabilities, increased lifetime of batteries, better estimating of SOC, SOH etc.

Optionally in some examples, including in at least one preferred example, the set of predetermined switching frequencies comprise one or more frequencies between 0.1 Hz to 10 KHz. A technical benefit may include enabling improved diagnostic capabilities, increased lifetime of batteries, better estimating of SOC, SOH etc.

Optionally in some examples, including in at least one preferred example, the processing circuitry is further configured to control the electrical connection between the battery pack and the traction system by controlling pre-charge transistor circuitry of the battery pack. A technical benefit may include decreasing a cost of providing in-situ EIS data as no additional hardware is required.

Optionally in some examples, including in at least one preferred example, the processing circuitry is further configured to, prior to obtaining the cell voltages and cell currents control the traction system to provide a short circuit to the battery pack; and control the pre-charge transistor circuitry to limit currents from the battery pack. A technical benefit may include decreasing a cost of providing in-situ EIS data as no additional hardware is required and that the controlled load enables improved diagnostic capabilities, increased lifetime of batteries, better estimating of SOC, SOH etc.

Optionally in some examples, including in at least one preferred example, the processing circuitry is further configured to obtain a plurality of first cell voltages as a series of first cell voltages, a plurality of first cell currents as a series of first cell currents synchronous to the series of first cell voltages; obtain, for each additional frequency of the set of predetermined switching frequencies, additional cell voltages as a series of additional cell voltages and a plurality of additional cell currents as a series of additional cell currents synchronous to the series of additional cell voltages, filter the series of first cell voltages and the series of first cell currents by a first filter, wherein the first filter is tuned to the first switching frequency, and filter, for each additional frequency of the set of predetermined switching frequencies, the series of additional cell voltage and the series additional cell currents by an additional filter, wherein the additional filter is tuned to the associated additional switching frequency. A technical benefit may include enabling improved diagnostic capabilities, increased lifetime of batteries, better estimating of SOC, SOH etc.

Optionally in some examples, including in at least one preferred example, the processing circuitry is further configured to diagnose the battery pack based on the obtained cell voltage/s, the obtained cell current/s and their associated switching frequency/ies, preferably by determining current state of health, SOH, of the battery pack and compare the current SOH to a previous SOH of the battery pack. A technical benefit may include enabling improved diagnostic capabilities, increased lifetime of batteries, better estimating of SOC, SOH etc.

Optionally in some examples, including in at least one preferred example, the processing circuitry is further configured to control operation of the battery pack based on the obtained cell voltage/s, the obtained cell current/s and their associated switching frequency/ies. A technical benefit may include enabling improved diagnostic capabilities, increased lifetime of batteries, better estimating of SOC, SOH etc.

Optionally in some examples, including in at least one preferred example, the processing circuitry is further configured to: during control, by the processing circuitry, of an electrical connection between a battery pack and a traction system of a vehicle at each additional switching frequency of the set of predetermined switching frequencies, for each additional switching frequency, synchronously obtain an additional cell voltage and an additional cell current of a battery cell of the battery pack; and provide the additional cell voltages, the additional cell currents and their associated additional switching frequencies for diagnostic of the battery cell; control the electrical connection between the battery pack and the traction system by controlling pre-charge transistor circuitry of the battery pack; control the traction system to provide a short circuit to the battery pack; and control the pre-charge transistor circuitry to limit currents from the battery pack; obtain a plurality of first cell voltages as a series of first cell voltages, a plurality of first cell currents as a series of first cell currents synchronous to the series of first cell voltages; obtain, for each additional frequency of the set of predetermined switching frequencies, additional cell voltages as a series of additional cell voltages and a plurality of additional cell currents as a series of additional cell currents synchronous to the series of additional cell voltages, filter the series of first cell voltages and the series of first cell currents by a first filter, wherein the first filter is tuned to the first switching frequency, and filter, for each additional frequency of the set of predetermined switching frequencies, the series of additional cell voltage and the series additional cell currents by an additional filter, wherein the additional filter is tuned to the associated additional switching frequency; diagnose the battery pack based on the obtained cell voltage/s, the obtained cell current/s and their associated switching frequency/ies, preferably by determining current state of health, SOH, of the battery pack and compare the current SOH to a previous SOH of the battery pack; control operation of the battery pack based on the obtained cell voltage/s, the obtained cell current/s and their associated switching frequency/ies; wherein the set of predetermined switching frequencies comprise one or more frequencies between 0.1 Hz to 10 kHz; and wherein the processing circuitry is further configured to: process the first cell voltage and the first cell current to provide a first frequency internal resistance of the battery cell, and provide the first frequency internal resistance for diagnostic of the battery cell. A technical benefit may include all of the benefits listed above and further enabling improved diagnostic capabilities, increased lifetime of batteries, better estimating of SOC, SOH etc.

According to a second aspect of the disclosure an energy storage system is presented. The energy storage system comprises at least one battery pack, at least one controllable connection between the at least one battery pack and a load and the computer system of the first aspect operatively connected to the controllable connection. A technical benefit may include being able to provide in-situ, i.e. during operation, EIS data from a battery pack or battery cell. This enables improved diagnostic capabilities, increased lifetime of batteries, better estimating of SOC, SOH etc.

According to a third aspect of the disclosure, a vehicle is presented. The vehicle, comprises a traction system and the energy storage system of the second aspect connected to the traction system. A technical benefit may include all of the benefits listed above and further enabling improved diagnostic capabilities, increased lifetime of batteries, better estimating of SOC, SOH etc.

According to a fourth aspect of the disclosure, a computer implemented method is presented. The method comprising: controlling, by processing circuitry of a computer system, an electrical connection between a battery pack and a traction system of a vehicle at a first switching frequency of a set of predetermined switching frequencies, during control of the electrical connection, synchronously obtaining, by the processing circuitry of the computer system, a first cell voltage and a first cell current of a battery cell of the battery pack; and providing, by the processing circuitry of the computer system, the first cell voltage, the first cell current and the first switching frequency for diagnostic of the battery cell. A technical benefit may include being able to provide in-situ, i.e. during operation, EIS data from a battery pack or battery cell. This enables improved diagnostic capabilities, increased lifetime of batteries, better estimating of SOC, SOH etc.

Optionally in some examples, including in at least one preferred example, the computer implemented method further comprises: controlling, by the processing circuitry of the computer system, the electrical connection between the battery pack and the traction system of the vehicle at each additional switching frequency of the set of predetermined switching frequencies; and during control of the electrical connection, for each additional switching frequency, synchronously obtaining, by the processing circuitry of the computer system, an additional cell voltage and an additional cell current of a battery cell of the battery pack; and providing, by the processing circuitry of the computer system, the additional cell voltages, the additional cell currents and their associated additional switching frequencies for diagnostic of the battery cell. A technical benefit may include providing the EIS data across a spectrum of frequencies, i.e. and EIS spectrum which enables further improved diagnostic capabilities, increased lifetime of batteries, better estimating of SOC, SOH etc.

According to a sixth aspect of the disclosure, a computer program product comprising program code is presented. The program code is for performing, when executed by a processing circuitry, the computer implemented method of the fifth aspect. A technical benefit may include providing the EIS data across a spectrum of frequencies, i.e. and EIS spectrum which enables further improved diagnostic capabilities, increased lifetime of batteries, better estimating of SOC, SOH etc.

According to a seventh aspect of the disclosure, a non-transitory computer-readable storage medium comprising instructions, which when executed by a processing circuitry, cause the processing circuitry to perform the computer implemented method of the fifth aspect. A technical benefit may include providing the EIS data across a spectrum of frequencies, i.e. and EIS spectrum which enables further improved diagnostic capabilities, increased lifetime of batteries, better estimating of SOC, SOH etc.

The disclosed aspects, examples (including any preferred examples), and/or accompanying claims may be suitably combined with each other as would be apparent to anyone of ordinary skill in the art. Additional features and advantages are disclosed in the following description, claims, and drawings, and in part will be readily apparent therefrom to those skilled in the art or recognized by practicing the disclosure as described herein.

There are also disclosed herein computer systems, control units, code modules, computer-implemented methods, computer readable media, and computer program products associated with the above discussed technical benefits.

### BRIEF DESCRIPTION OF THE DRAWINGS

Examples are described in more detail below with reference to the appended drawings.

FIG. 1 is an exemplary side view of a vehicle according to an example.

FIG. 2 is an exemplary block diagram of a vehicle according to an example.

FIG. 3A is an exemplary block diagram of a computer system connected to a battery pack, a switch device and a load according to an example.

FIG. 3B is an exemplary block diagram of a computer system connected to a load and a battery pack comprising switch devices.

FIG. 4 is an exemplary block diagram of a battery pack according to an example.

FIG. 5 is an exemplary block diagram of an EIS controller according to an example.

FIG. 6 is an exemplary block diagram of a computer system connected to a battery pack, a switch device and a load according to an example.

FIG. 7 is an exemplary block diagram of a method according to an example.

FIG. 8 is an exemplary block diagram of an energy storage system according to an example.

FIG. 9 is an exemplary block diagram of a vehicle according to an example.

FIG. 10 is an exemplary block diagram of a battery pack according to an example.

FIG. 11 is an exemplary block diagram of a computer program product according to an example.

FIG. 12 is a schematic diagram of an exemplary computer system for implementing examples disclosed herein, according to an example.

### DETAILED DESCRIPTION

The detailed description set forth below provides information and examples of the disclosed technology with sufficient detail to enable those skilled in the art to practice the disclosure.

In order to accurately estimate a remaining capacity, a state of charge (SOC), or other characteristics (e.g. temperature, internal faults etc.) of a battery pack or a battery cell, detailed data of the battery is required. Some solutions estimate an internal resistance of the battery, determine a voltage drop during loading, or simply monitor a current cell voltage to estimate the SOC of the battery. The SOC may be estimated based on a model of the battery where current data is mapped onto the model to estimate a current SOC. Generally the more data that may be provided, the better an estimation of a current state of a battery e.g. SOC, state of health SOH etc. A battery pack may comprise a plurality of battery cells and accurate data of the battery pack may be utilized to provide estimates of the battery cells regarding e.g. SOC, SOH, temperature, voltage, current, internal resistance, rate of self-discharge, peak discharge current etc.

If a battery is disconnected from its load and brought into a testing environment, detailed analysis of the battery may be performed to accurately determine a state of the battery. Some of these analysis are generally destructive, such as half-cell analysis and other are complex requiring specialized equipment and complex test setups such as electrochemical impedance spectroscopy (EIS).

EIS is a powerful technique for studying an electrochemical processes that occur in batteries. EIS generally works by applying an alternating current (AC) signal of controlled amplitude to the battery and synchronously measuring resulting AC voltage and AC current responses. The impedance of the battery is then calculated from a relationship between the resulting AC voltage to the resulting AC current.

EIS is useful in studying a wide range of battery phenomena. EIS may be used to determine charge transfer kinetics of the battery, i.e. the rate at which ions are transferred between the electrodes and the electrolyte. The charge transfer kinetics may be used to optimize the design of battery electrodes and electrolytes. EIS may be useful in determining diffusion of the battery, i.e. the rate at which ions diffuse through the battery electrodes and electrolytes. This information may be used to e.g. improve the performance of batteries at high charge and discharge rates. EIS may further be utilized to determine a solid electrolyte interphase (SEI) formation of the battery, i.e. EIS may be used to monitor the formation and growth of the SEI on the surface of the battery electrodes. The SEI is a thin layer that forms on the electrodes during the first few cycles of battery operation. It plays an important role in protecting the electrodes from degradation and volumetric changes of the electrodes may damage the SEI and cause degrading the electrodes. EIS may further be utilized to determine a battery degradation, i.e. EIS may be used to track changes in e.g. the impedance of the battery over time. These changes can be used to identify and diagnose battery degradation mechanisms. Generally, EIS is a non-destructive technique making it an ideal tool for studying batteries under a variety of operating conditions.

The present disclosure will provide a system, method and other devices configured to obtain EIS data from a battery during use, i.e. in-situ. This allows EIS data to be measured, acquired otherwise obtained without having to disconnect the battery from a load. In an electrical vehicle, very detailed data may be provided without having to remove the battery from the vehicle or discontinue providing power to a load of the battery. This enables improved diagnostic capabilities of the battery. A current SOH, SOC or remaining capacity of the battery may be accurately estimated reducing a risk that the battery is discharged too deeply which may damage the battery. It further allows for more accurate estimates of a remaining distance a battery operated vehicle may travel, it provides more accurate data on when a battery pack, or specific battery cells of a battery pack are in need of maintenance or service.

One specific examples of how EIS may be utilized in a vehicle is to better determine SOC at situations where it is otherwise challenging to accurately estimate the SOC. Chemistries such as LFP and LMFP are typically complicated when it comes to determine SOC from other data. Another specific example of how EIS may be utilized in a vehicle is to better determine an internal temperature of a battery pack. Generally, an amount of sensors configured to obtain data relevant for specific cells of a battery pack are low. Both of these examples are advantageous in optimizing, i.e. increasing an efficiency of, a usage and lifetime of the battery. Specifically, SOC is important for providing the driver optimized range/charging and range estimation.

The present disclosure may be implemented on energy systems comprising multiple battery packs allowing EIS data to be acquired from one battery back whilst other battery packs may provide power to an electrical motor or receive power from a charger. One may note that the current of one battery pack generally affects the current of the other battery packs. That is to say, some EIS analysis may be performed (while driving/charging) on cells in multiple packs while only alternating the connection of one pack.

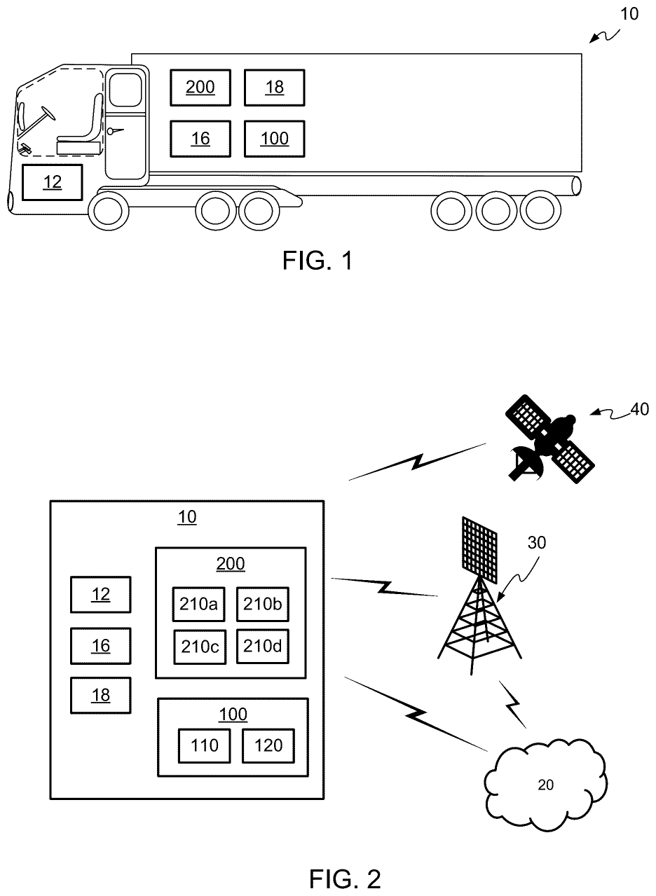

FIG. 1 is an exemplary schematic side view of a heavy-duty vehicle 10 (hereinafter referred to vehicle 10 for reasons of brevity). This particular vehicle 10 comprises a tractor unit 10a which is arranged to tow a trailer unit 10b. In other examples, other heavy-duty vehicles may be employed, e.g., trucks, buses, and construction equipment. Although not explicitly visualized in FIG. 1, the skilled person will appreciate that the vehicle 10 comprises all necessary vehicle units and associated functionality such that it may operate as the skilled person would expect of a vehicle 10, such as a powertrain, chassis, and various control systems. Emphasis in the present disclosure is rather directed at electrical currents of the vehicle 10, and therefore functionality and features related this will be the focus of the present disclosure. However, the vehicle 10 comprises one or more propulsion sources 12. The propulsion source 12 may be any suitable propulsion source 12 exemplified by, but not limited to, one or more or a combination of an electrical motor, a combustion engine such as a diesel, gas or gasoline powered engine. At least one propulsion source 12 is an electrical motor. The vehicle 10 further comprises at least one energy source 200 suitable for providing energy for the propulsion source(s) 12. That is to say, as at least one propulsion source 12 is an electrical motor, at least one propulsion source 12 is a battery pack 200. The vehicle 10 further comprises sensor circuitry 16 arranged to detect, measure, sense or otherwise obtain data relevant for operation of the vehicle 10. The data relevant for operation of the vehicle 10 may be exemplified by, but not limited to, one or more of a voltage of the battery pack 200, a current provided by the battery pack 200, a speed of the vehicle 10, a weight of the vehicle 10, an inclination of the vehicle 10, a status (state of charge, fuel level etc.) of the energy source 200 of the vehicle 10 etc. Advantageously, the vehicle 10 further comprises communications circuitry 18 configured for communication with, to the vehicle 10, external devices. The vehicle 10 further comprises a computer system 100.

As shown in FIG. 2, the vehicle 10 may communicate with a cloud server 20 using the communications circuitry 18. The communications circuitry 18 may be configured to communicate with the cloud server 20 directly, or via a communications interface such as a cellular communications interface exemplified by a radio base station 30 in FIG. 2. The cloud server 20 may be any suitable cloud server exemplified by, but not limited to, Amazon Web Services (AWS), Microsoft Azure, Google Cloud Platform (GCP), IBM Cloud, Oracle Cloud Infrastructure (OCI), DigitalOcean, Vultr, Linode, Alibaba Cloud, Rackspace etc. The communications interface is advantageously a wireless communications interface exemplified by, but not limited to, Wi-Fi, Bluetooth, Zigbee, Z-Wave, LoRa, Sigfox, 2G (GSM, CDMA), 3G (UMTS, CDMA2000), 4G (LTE), 5G (NR) etc. The vehicle 10 may further, via the communications circuitry 18, be operatively connected to a Global Navigation Satellite System (GNSS) 40 exemplified by, but not limited to, global positioning system (GPS), Globalnaya Navigatsionnaya Sputnikovaya Sistema (GLONASS), Galileo, BeiDou Navigation Satellite System, Navigation with Indian Constellation (NavIC) etc. The vehicle 10 may be configured to utilize data obtain from the GNSS 40 to determine a geographical location of the vehicle 10.

As mentioned, a vehicle 10 according to the present disclosure is an, at least partly, electrically propelled vehicle. To this end, the vehicle 10 of the present disclosure comprises at least one energy source 200 in the form of an electrical energy source 200, i.e. at least one battery pack 200. The vehicle battery pack 200 comprises one or more battery cells 210a, 210b, 210c, 210d. In FIG. 2, the battery pack 200 is shown comprising four battery cells 210a, 210b, 210c, 210d. However, this is for illustrative purposes, and the battery pack 200 may comprise any number of battery cells 210a, 210b, 210c, 210d. The battery pack 200 is advantageously configured to provide energy at least to the propulsion source 12 of the vehicle 10. Additionally, or alternatively, the battery pack 200 may be configured to provide energy to other part components of the vehicle 10 such as, but not limited to, vehicle electronics, climate control of the vehicle 10, safety functions of the vehicle etc.

The computer system 100 of the vehicle 10 is advantageously operatively connected to the communications circuitry 18, the sensor circuitry 16, the battery pack 200 and/or the propulsion source 12 of the vehicle 10. The computer system 100 comprises processing circuitry 110. The computer system 100 may comprise a storage device 120, advantageously a non-volatile storage device such as a hard disk drives (HDDs), solid-state drives (SSDs) etc. In some examples, the storage device 120 is operatively connected to the computer system 100.

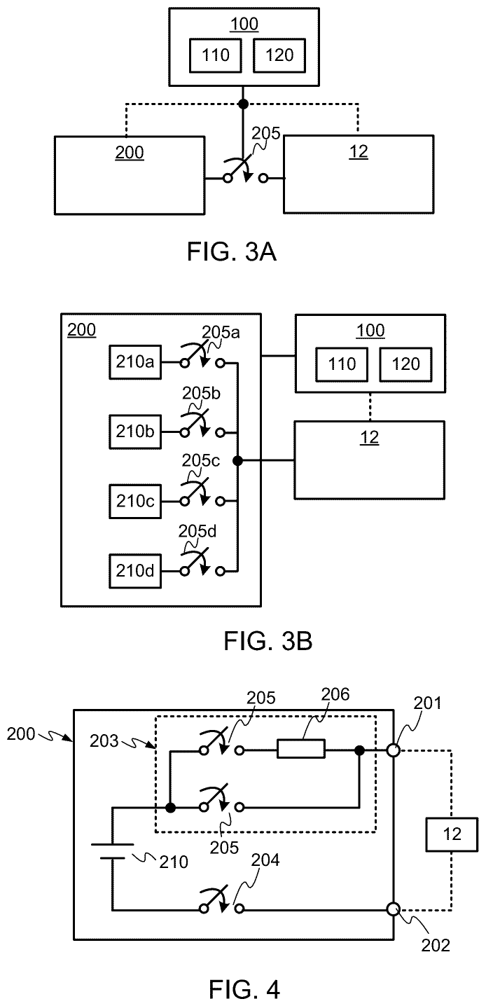

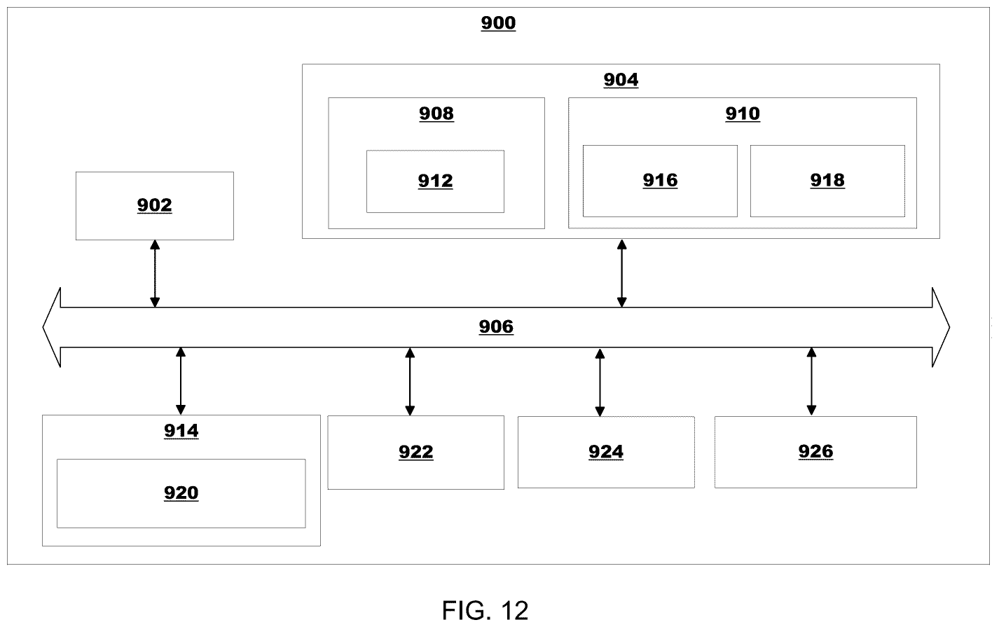

In FIG. 3A, one example of the computer system 100 is shown. In FIG. 3A, the computer system 100 is operatively connected to control a switch device 205 arranged to selectively connect the battery pack 200 to a load 12. In FIG. 12, the load 12 is the traction system 12, e.g. the propulsion source 12 of the vehicle 10.

In FIG. 3B, one example of the computer system 100 is shown. In FIG. 3B, the battery pack 200 is shown comprising a plurality of battery cells 210a, 210b, 210c, 210d. Each battery cell 210a, 210b, 210c, 210d is selectively connectable to the load 12 (e.g. the traction system 12 of the vehicle 10) by a respective switch device 205a, 205b, 205c, 205d. The computer system 100 is operatively connected to control the switch devices 205a, 205b, 205c, 205d arranged to selectively connect the battery pack 200 to a load 12. Is should be mentioned that, in e.g. vehicle applications, a plurality of cells 210a, 210b, 210c, 210d are generally connected in series. In such implementations and for the present disclosure, a plurality of cells connected in series may be regarded as one cell.

Regardless of the configuration of the battery pack 200, and the connection of the computer system 100, the computer system 100 may advantageously be operatively connected to the battery pack 200 and/or the propulsion source 12. The processing circuitry 110 of the computer system 100 may be configured to obtain data from the switch device 205, the battery pack 200 and/or the propulsion source 12. The data obtained may be exemplified as, but not limited to, a position of the switch device 205, a mode of operation of the load 12, a current into/out from the load 12, a voltage at the load 12, a current into/out from the switch device 205, a voltage at the switch device 205, a current into/out from the battery pack 200 and or a voltage at the battery pack 200 (or cell voltage within the battery pack 200). Additionally, or alternatively, the processing circuitry 110 of the computer system 100 may be configured to control the switch device 205, the battery pack 200 and/or the propulsion source 12. The processing circuitry 110 of the computer system 100 may be configured to control a position (state) of the switch device 205. The switch device 205 may controllable between two or more positions (states) such as, but not limited to, open, closed, pre-charge etc. The processing circuitry 110 of the computer system 100 may be configured to control the propulsion source 12, i.e. an electrical machine, to present (provide) a pre-determined load to the switch device 205, and indirectly to the battery pack 200. This may be provided by e.g. vector control of an inverter of the electrical machine through which an impedance presented to the switch device 205, and indirectly to the battery pack 200, may be controlled. In some examples, the processing circuitry 110 may be configured to present (provide) a pre-determined load to the switch device 205 by controlling a heating element or such device operatively connected to the battery pack 200.

The examples presented in reference to FIG. 3A and FIG. 3B should not be considered exhaustive and their respective features may very well be combined. Further to this not all battery cells 210a, 210b, 210c, 210d are required to be associated with a dedicated switch devices 205a, 205b, 205c, 205d. In some examples, one or more battery cells 210a, 210b, 210c, 210d are connected in series and may be selectively connected to the load by a common switch device 205a, 205b, 205c, 205d. In some examples two or more switch device are connected in parallel and arranged to be selectively connected to the load 12 by a common switch device 205a, 205b, 205c, 205d. All examples may be suitably combined to form further working examples of the present disclosure.

As shown in FIG. 4, the switch device 205 may form part of a pre-charge circuitry 203 of the battery pack 200. The pre-charge circuit 203 is provided in order to limit a current flowing into a load during startup of a system. At startup of the system, capacitive part of the load may be completely discharged and the pre-charge circuit 203 will control the current used to charge the capacitive part of the load. In FIG. 4, the pre-charge circuitry 203 is connected to a battery cell 210 of the battery pack 200. If the battery pack 200 comprise more than one battery cell 210, all, or some, of the battery cells 210 may be connected to a respective pre-charge circuitry 203. Further, in some examples, the pre-charge circuitry 203 may be external to the battery pack 200 or arranged such that the same pre-charge circuit 203 is connected to all battery cells 210 of the battery pack 200. If more than one battery pack 200 is provided, some, or all, battery packs 200 may share a common pre-charge circuitry 203.

The pre-charge circuitry 205 comprises at least one pre-charge switch 205 and a pre-charge impedance 206. The pre-charge impedance 206 may be a pre-charge resistor 206. In FIG. 4, the pre-charge circuitry 203 comprises two pre-charge switches 205, this is an optional arrangement and in some examples, the pre-charge circuitry 203 comprise only one pre-charge switch 205. The pre-charge circuitry 203 is configured to selectively connect the battery cell 210 to a load 12 (e.g. the traction system 12 of the vehicle 10) either directly or through the pre-charge impedance 206. Generally, as shown in FIG. 4 the battery pack 200 may comprise further switches 204 arranged to ensure that both poles 201, 202 of the battery pack 210 are disconnected from the battery cell(s) 210.

In examples of the present disclosure comprising a pre-charge circuitry 203, the switch devices 205, 205a, 205b, 205c, 205d introduced with reference to FIG. 3A and FIG. 3B are advantageously provided by the pre-charge switch 205 of the pre-charge circuitry 203. This reduces a cost of implementing the teachings presented herein as fewer additional components are required.

It should be mentioned that the switch devices 205, 205a, 205b, 205c, 205d may be any suitable switch device being capable of controlled switching at switching frequencies of 0.1 Hz and above. Consequently, the switch devices 205, 205a, 205b, 205c, 205d may formed as an electromechanical switch such as a relay or even solenoids. However, it is advantageous if the switching frequency may go above 1 kHz, preferably up to 10 kHz. In some examples the switching frequency may go above 10 kHz and even above 50 kHz. At higher frequencies, i.e. above 100 Hz, the switch device 205, 205a, 205b, 205c, 205d is advantageously a semiconductor based switch such a transistor. Depending on an expected current and switching frequency, different technologies of transistors may be employed such as, but not limited to, bipolar junction transistor (BJT), field-effect transistors (FET), metal-oxide-semiconductor field-effect transistor (MOSFET), insulated gate bipolar junction transistor (IGBT) etc.

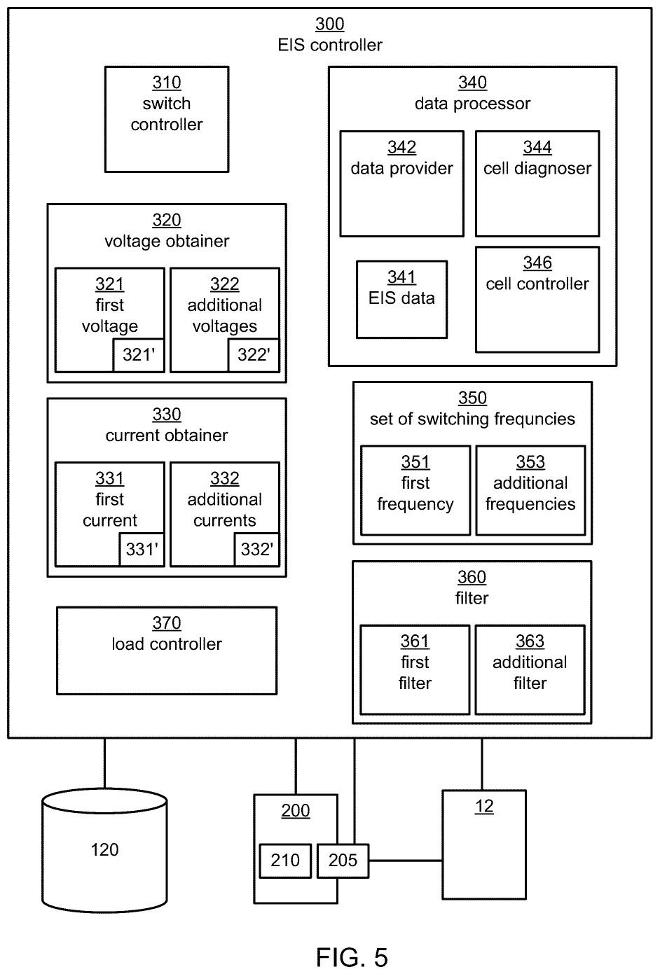

In FIG. 5, a block diagram of an exemplary EIS controller 300 is shown. The EIS controller 300 is configured to provide in-situ, i.e. during use, EIS data 341 for a battery pack 200 and/or a battery cell 210. The computer system 100, specifically the processing circuitry 110 of the computer system 100, may be configured to provide some or all of the functions and features of the EIS controller 300.

The EIS controller 300 comprises a switch controller 310 configured to control an electrical connection between the battery pack 200, and/or one or more battery cells 210 of the battery pack 200, and the load 12. The control of the electrical connection is advantageously provided by control of a switch device 205 of the battery pack 200 or connected between the battery pack 200 and the load 12. The control of the electrical connection, e.g. the switch device 205, is performed at a switching frequency selected from a set of predetermined switching frequencies 350, a set of switching frequencies 350 for short. The switch controller 310 may be configured to control the electrical connection, e.g. the switch device 205, at a first frequency 351 of the set of switching frequencies 350 or at one or more additional switching frequencies 353 of the set of switching frequencies 350. When active, the switch controller 310 is configured to control the switch device 205 at one frequency of the set of switching frequencies 350 at a time. The switch controller 310 may be configured to step through the frequencies 351, 353 of the set of switching frequencies 350. In some examples, the set of switching frequencies 350 is defined by a frequency range such as 0.1 Hz to 10 kHz, and the switch controller 310 may randomly select the first frequency 351 and optionally any additional frequencies 353 within the frequency range defined by the set of switching frequencies 350. In some examples, the switch controller 310 may step through the frequency range defined by the set of switching frequencies 350 at a predetermined or random frequency step size. In some examples, the step size is linear. In some examples, the step size is logarithmic.

The EIS controller 300 further comprise a voltage obtainer 320. The voltage obtainer 320 is configured to obtain, measure or otherwise acquire at least a first voltage 321 of the battery pack 200 or the battery cell 210 for which EIS data 341 is requested. Generally, a voltage relating to a battery cell 210 may be referred to as a cell voltage and a voltage relating to a battery pack 200 may be referred to as a pack voltage. Optionally, the voltage obtainer 320 may be configured to obtain one or more additional voltages 322 of the battery pack 200 or the battery cell 210 for which EIS data 341 is requested. The voltage obtainer 320 may obtain the voltages 321, 322 from e.g. the previously presented sensor circuitry 16, the battery pack 200 and/or the battery cell 210. The voltage obtainer 320 may be configured to obtain the first voltage 321 not as one single value at one point in time, but as a series of first voltages 321′ obtained over a time period. Correspondingly, the voltage obtainer 320 may be configured to obtain the additional voltages 322 not as one single value at one point in time, but as a series of additional voltages 322′ obtained over a time period.

The EIS controller 300 further comprise a current obtainer 330. The current obtainer 330 corresponds to the voltage obtainer 320 but is configured to obtain, measure or otherwise acquire at least a first current 331 of the battery pack 200 or the battery cell 210 for which EIS data 341 is requested. Generally, a current relating to a battery cell 210 may be referred to as a cell current and a current relating to a battery pack 200 may be referred to as a pack current. Optionally, the current obtainer 330 may be configured to obtain one or more additional currents 332 of the battery pack 200 or the battery cell 210 for which EIS data 341 is requested. The current obtainer 330 may obtain the currents 331, 333 from e.g. the previously presented sensor circuitry 16, the battery pack 200, the battery cell 210 and/or the switch device 205. The current obtainer 330 may be configured to obtain the first current 331 not as one single value at one point in time, but as a series of first currents 331′ obtained over a time period. Correspondingly, the current obtainer 330 may be configured to obtain the additional currents 332 not as one single value at one point in time, but as a series of additional currents 332′ obtained over a time period.

The voltage obtainer 320 and the current obtainer 330 are configured to work synchronously. That is to say, the first voltage 321 and the first current 331 are obtained at substantially the same point in time. Correspondingly, any additional voltages 322 and additional currents 332 are obtained at substantially the same respective points in time. The same applies to each value of the series of first voltages 321′ together with the corresponding value of the series of first currents 331′, and each value of the series of additional voltages 322′ together with the corresponding value of the series of additional currents 332′.

Is should be mentioned that parts, components, devices etc. that need to synchronize the frequency operation (voltage measurement, current measurement, connection-switch-control) are generally already connected to the same processor circuitry, enabling a more optimal and fast operation compared to having the switching control being done comparably far away in the system as it would be if utilizing an inverter.

It should be mentioned that he EIS controller 300 may very well comprise more than one voltage obtainer 320 and one current obtainer 330. More voltage obtainers 320 and one current obtainers 330 may increase a sampling frequency of the series of voltages 321′, 322′ the series of currents 331′, 332. Further to this, if e.g. the switch device 205 is operating at pack level, i.e. as shown in FIG. 3A (or several switch devices 205a, 205b, 205c, 205d area controlled in parallel), one voltage obtainer 320 and one current obtainer 330 may be provided for each battery cells 210a, 210b, 210c, 210d (or some of the battery cells 210a, 210b, 210c, 210d) such that EIS data 341 for a plurality of battery cells 210a, 210b, 210c, 210d may be provided in parallel.

The EIS controller 300 further comprises a data processor 340. The data processor 340 is configured to form the EIS data 341 such that it comprises a voltage 321, 322 obtained by the voltage obtainer 320 and a synchronously obtained current 331, 332 obtained by the current obtainer 330. The EIS data 341 further comprises a switching frequency 351, 353 at which the switch controller 310 operated the switch device 205 during the synchronous obtaining of the voltage 321, 322 by the voltage obtainer 320 and the current 331, 332 by the current obtainer 330.

The data processor 340 may further process the obtained voltages and currents 321, 322, 331, 332 (or series of voltages and currents 321′, 322′, 331′, 332′) by determining an internal impedance (resistance) of the battery pack 200 or battery cell 210. The data processor 340 may further process the obtained voltages and currents 321, 322, 331, 332 (or series of voltages and currents 321′, 322′, 331′, 332′) by determining an internal impedance of the battery pack 200 or battery cell 210. The determined impedance and/or the internal resistance may be comprised in the EIS data 341.

In case the voltage obtainer 320 and the current obtainer 330 obtain series of voltages and currents 321′, 322′, 331′, 332′, the data processor 340 may be configured to filter the series of voltages and currents 321′, 322′, 331′, 332′ by a filter 360. The filter 360 may separate filters tuned for each of the frequencies of the set of switching frequencies 350 such that a first filter 361 is tuned to the first frequency 351 and additional filters 363 are tuned to the additional frequencies 353. Advantageously, the filter 360 is a tunable filter such that the data processor 340 may control the filter 360 to tune it to a switching frequency 351, 353 at which the series of voltages and currents 321′, 322′, 331′, 332′ were/is obtained.

The data processor 340 may further process the series of voltages and currents 321′, 322′, 331′, 332′ by determining a mean, a standard deviation, a peak value, a minimum value etc. of the series of voltages and currents 321′, 322′, 331′, 332′.

The data processor 340 may comprise a data provider 342 configured to provide the EIS data 341 for further processing, storage and/or diagnostic of the battery pack 200 or battery cell 210. The data provider 342 may be configured to store the EIS data 341 at the storage device 120 of the computer system 100.

The data processor 340 may further comprise a cell diagnoser 344 configured to diagnose the battery back 200 and/or the battery cell 210 based on the EIS data 341. Such diagnosis may comprise determining any metric obtained from EIS data 341 such as, but not limited to, an SOH, an SOC, a diffusion, an SEI formation etc. The data determined metrics may be provided to the storage device 120 by the data provide 342 and/or comprised in the EIS data 341. The cell diagnoser 344 may further be configured to compare a determined metric, including impedance and/or resistance, to corresponding historic metrics (obtained from e.g. the storage device 120) to determine a rate of deterioration or simply to detect changes in the determined metrics.

The data processor 340 may further comprise a cell controller 345 configured to control the battery pack 200 and/or the battery cell 210 based on the EIS data 341. Such control may comprise preventing the battery pack 200 or battery cell 210 to be discharged too deeply and/or actively limit a current from a battery cell 210 to provide equal currents from all battery cells 210 of a battery pack 200.

The EIS controller 300 may further comprise a load controller 370. The load controller 370 is configured to control the load 12 such that the load 12 presents a desired impedance to the battery switch device 205. In the preferred example, the load 12 is a traction system 12 of a vehicle 10 and the impedance of the load may be controlled by manipulating and inverter of the traction system 12 to present the desired impedance. The desired impedance may be referred to as a controlled discharge impedance, or discharge impedance for short. For instance, by controlling the inverter not to change phases (in a three-phase inverter), only one winding will be presented to the battery pack 200 which, after charging of the winding, will manifest itself as a short circuit. In order to reduce a risk of damaging the load 12, the switch controller 310 may be configured to limit a current provided by the battery pack 200 by e.g. PWM-control of the switch device 205 and/or connecting the pre-charge impedance 206 in the flow of current into the load 12. In some examples, short circuit may be interpreted as low impedance, e.g. an impedance below 25 (2.

The EIS controller 300 enables provisioning of EIS data 341 during use of a battery pack 200. In order not to disrupt functionality of the load 12, it is advantageous to only control, by the switch controller 310, some of the switch devices 205 between the load 12 and a power source 200, 210. To exemplify, if the load is an electrical motor (an electrical propulsion source) of the vehicle 10 and the vehicle only comprise one battery pack 200, controlling a common switch device (see FIG. 3A) is likely to affect operation of the vehicle 10. During stand still, the load controller 370 may be utilized to enable EIS data 341 also in such an example. However, if more than one battery pack 200 is available to provide power to the electrical motor, controlling a switch device 205 of one battery back 200 is unlikely to affect operation of the vehicle 10 as the other battery pack 200 will compensate for any power lost due to switching. Further, if only any battery pack 200 is available (or there are other reasons for not wanting to obtain EIS data 341 on battery pack level), switch devices 205a, 205b, 205c, 205d of only one or some of the battery cells 210a, 210b, 210c, 210d may be controller by the switch controller 310 such that EIS data 341 is obtained on a battery cell level. The latter example will also enable acquiring of EIS data 341 during operation of e.g. a vehicle 10, even if it is being propelled by the electrical motor 12.

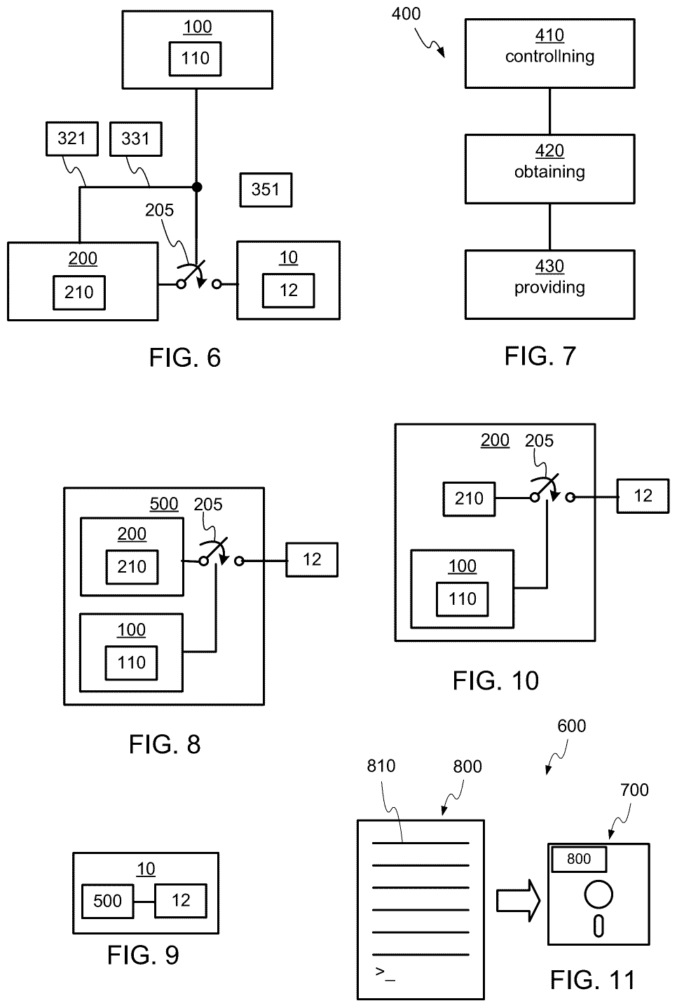

In FIG. 6 one preferred example of a computer system 100 according to the present disclosure is presented. The computer system 100 comprises processing circuitry 110 configured to, during control, by the processing circuitry 110, of an electrical connection between a battery pack 200 and a traction system 12 of a vehicle 10 at a first switching frequency 351 of a set of predetermined switching frequencies 350, synchronously obtain a first cell voltage 321 and a first cell current 331 of a battery cell 210 of the battery pack 200. The processing circuitry 110 is further configured to provide the first cell voltage 321, the first cell current 331 and the first switching frequency 351 for diagnostic of the battery cell 210.

With reference to FIG. 7, a method 400 for providing EIS data 341 from a battery pack 200 or battery cell 210 will be presented. The method is advantageously a computer implemented method 400. The processing circuitry 110 of the previously presented computer system 100 may be configured to perform, or cause the performance of, some or all features of the method 400. It should be mentioned that the method 400 is only described in short for reasons of brevity and the method 400 may very well be expanded, modified or otherwise altered to comprise any of the further features, functions or examples presented herein; specifically those presented in reference to the EIS controller 300 in FIG. 5.

The method 400 comprises controlling 410 a connection between a battery pack 200 and a traction system 12 of a vehicle 10 at a first switching frequency 351 of a set of predetermined switching frequencies 350. The controlling 410 may advantageously be performed as exemplified in reference to the switch controller 310 introduced in reference to FIG. 5. The method 400 further comprises, during the controlling 410, synchronously obtaining 420 a first cell voltage 321 and a first cell current 331 of a battery cell 210 of the battery pack 200. The obtaining 420 may advantageously be performed as exemplified in reference to the voltage obtainer 320 and/or the current obtainer 330 of the EIS controller 310 introduced in reference to FIG. 5. The method 400 further comprises providing 430 the first cell voltage 321, the first cell current 331 and the first switching frequency 351 for diagnostic of the battery cell 210. The providing 420 may advantageously be performed as exemplified in reference to the data processor 340 introduced in reference to FIG. 5.

As mentioned, the method 400 may very well be expanded to comprise any other feature presented herein, such as some or all features introduced in reference to the load controller 370 or any other feature of the EIS controller 300.

In FIG. 8, an exemplary energy storage system 500 is shown. The energy storage system 500 comprises one or more battery packs 200. The battery packs 200 may be any suitable battery pack 200 presented herein. The energy storage system 500 further comprises at least one controllable connection 205 between the battery pack 200 and a load 12. The load 12 may be a traction system 12 of a vehicle 10. The controllable connection 205 is advantageously the previously presented switch device 205. The energy storage system 500 further comprises the previously presented computer system 100 and processing circuitry 110 configured to provide or cause, e.g. any function, feature or example presented in reference to the EIS controller 300.

In FIG. 9, a block diagram of a vehicle 10 comprising a traction system 12 operatively connected to the energy storage system 500 introduced with reference to FIG. 8.

Although the present disclosure has been focused on providing EIS data 341 at a system level. The features of the computer system 100 and associated processing circuitry 110 presented herein may very well be applied on lower levels as well. To this end, FIG. 10 shows a battery pack 200 composing at least one battery cell 210 connectable to an external load 12 by a switch device 205. The battery pack 200 of FIG. 10 further comprises the computer system 100, or at least part of the processing circuitry 110 of the computer system 100 presented herein.

In FIG. 11 a computer program product 600 is shown. The computer program product 600 comprises a computer program 800 and a non-transitory computer readable medium 700. The computer program 800 may be stored on the computer readable medium 700. The computer readable medium 700 is, in FIG. 11, exemplified as a vintage 5.25″ floppy disc, but may be embodied as any suitable non-transitory computer readable medium such as, but not limited to, hard disk drives (HDDs), solid-state drives (SSDs), optical discs (e.g., CD-ROM, DVD-ROM, CD-RW, DVD-RW), USB flash drives, magnetic tapes, memory cards, Read-Only Memories (ROM), network-attached storage (NAS), cloud storage etc.

The computer program 800 comprises instruction 810 e.g. program instruction, software code, that, when executed by processing circuitry cause the processing circuitry to perform the method 400 introduced with reference to FIG. 7.

FIG. 12 is a schematic diagram of a computer system 900 for implementing examples disclosed herein. The computer system 900 of FIG. 12 may be the computer system 100 introduced with reference to FIG. 1. The computer system 900 is adapted to execute instructions from a computer-readable medium to perform these and/or any of the functions or processing described herein. The computer system 900 may be connected (e.g., networked) to other machines in a LAN, an intranet, an extranet, or the Internet. While only a single device is illustrated, the computer system 900 may include any collection of devices that individually or jointly execute a set (or multiple sets) of instructions to perform any one or more of the methodologies discussed herein. Accordingly, any reference in the disclosure and/or claims to a computer system, computing system, computer device, computing device, control system, control unit, electronic control unit (ECU), processor device, processing circuitry, etc., includes reference to one or more such devices to individually or jointly execute a set (or multiple sets) of instructions to perform any one or more of the methodologies discussed herein. For example, control system may include a single control unit or a plurality of control units connected or otherwise communicatively coupled to each other, such that any performed function may be distributed between the control units as desired. Further, such devices may communicate with each other or other devices by various system architectures, such as directly or via a Controller Area Network (CAN) bus, etc.

The computer system 900 may comprise at least one computing device or electronic device capable of including firmware, hardware, and/or executing software instructions to implement the functionality described herein. The computer system 900 may include processing circuitry 902 (e.g., processing circuitry including one or more processor devices or control units), a memory 904, and a system bus 906. The processing circuitry 902 may be the processing circuitry 110 introduced in reference to FIG. 2. The computer system 900 may include at least one computing device having the processing circuitry 902. The system bus 906 provides an interface for system components including, but not limited to, the memory 904 and the processing circuitry 902. The processing circuitry 902 may include any number of hardware components for conducting data or signal processing or for executing computer code stored in memory 904. The processing circuitry 902 may, for example, include a general-purpose processor, an application specific processor, a Digital Signal Processor (DSP), an Application Specific Integrated Circuit (ASIC), a Field Programmable Gate Array (FPGA), a circuit containing processing components, a group of distributed processing components, a group of distributed computers configured for processing, or other programmable logic device, discrete gate or transistor logic, discrete hardware components, or any combination thereof designed to perform the functions described herein. The processing circuitry 902 may further include computer executable code that controls operation of the programmable device.

The system bus 906 may be any of several types of bus structures that may further interconnect to a memory bus (with or without a memory controller), a peripheral bus, and/or a local bus using any of a variety of bus architectures. The memory 904 may be one or more devices for storing data and/or computer code for completing or facilitating methods described herein. The memory 904 may include database components, object code components, script components, or other types of information structure for supporting the various activities herein. Any distributed or local memory device may be utilized with the systems and methods of this description. The memory 904 may be communicably connected to the processing circuitry 902 (e.g., via a circuit or any other wired, wireless, or network connection) and may include computer code for executing one or more processes described herein. The memory 904 may include non-volatile memory 908 (e.g., read-only memory (ROM), erasable programmable read-only memory (EPROM), electrically erasable programmable read-only memory (EEPROM), etc.), and volatile memory 910 (e.g., random-access memory (RAM)), or any other medium which can be used to carry or store desired program code in the form of machine-executable instructions or data structures and which can be accessed by a computer or other machine with processing circuitry 902. A basic input/output system (BIOS) 912 may be stored in the non-volatile memory 908 and can include the basic routines that help to transfer information between elements within the computer system 900.

The computer system 900 may further include or be coupled to a non-transitory computer-readable storage medium such as the storage device 914, which may comprise, for example, an internal or external hard disk drive (HDD) (e.g., enhanced integrated drive electronics (EIDE) or serial advanced technology attachment (SATA)), HDD (e.g., EIDE or SATA) for storage, flash memory, or the like. The storage device 914 and other drives associated with computer-readable media and computer-usable media may provide non-volatile storage of data, data structures, computer-executable instructions, and the like.

Computer-code which is hard or soft coded may be provided in the form of one or more modules. The module(s) can be implemented as software and/or hard-coded in circuitry to implement the functionality described herein in whole or in part. The modules may be stored in the storage device 914 and/or in the volatile memory 910, which may include an operating system 916 and/or one or more program modules 918. All or a portion of the examples disclosed herein may be implemented as a computer program 920 stored on a transitory or non-transitory computer-usable or computer-readable storage medium (e.g., single medium or multiple media), such as the storage device 914, which includes complex programming instructions (e.g., complex computer-readable program code) to cause the processing circuitry 902 to carry out actions described herein. Thus, the computer-readable program code of the computer program 920 can comprise software instructions for implementing the functionality of the examples described herein when executed by the processing circuitry 902. In some examples, the storage device 914 may be a computer program product (e.g., readable storage medium) storing the computer program 920 thereon, where at least a portion of a computer program 920 may be loadable (e.g., into a processor) for implementing the functionality of the examples described herein when executed by the processing circuitry 902. The processing circuitry 902 may serve as a controller or control system for the computer system 900 that is to implement the functionality described herein.

The computer system 900 may include an input device interface 922 configured to receive input and selections to be communicated to the computer system 900 when executing instructions, such as from a keyboard, mouse, touch-sensitive surface, etc. Such input devices may be connected to the processing circuitry 902 through the input device interface 922 coupled to the system bus 906 but can be connected through other interfaces, such as a parallel port, an Institute of Electrical and Electronic Engineers (IEEE) 1394 serial port, a Universal Serial Bus (USB) port, an IR interface, and the like. The computer system 900 may include an output device interface 924 configured to forward output, such as to a display, a video display unit (e.g., a liquid crystal display (LCD) or a cathode ray tube (CRT)). The computer system 900 may include a communications interface 926 suitable for communicating with a network as appropriate or desired.

The operational actions described in any of the exemplary aspects herein are described to provide examples and discussion. The actions may be performed by hardware components, may be embodied in machine-executable instructions to cause a processor to perform the actions, or may be performed by a combination of hardware and software. Although a specific order of method actions may be shown or described, the order of the actions may differ. In addition, two or more actions may be performed concurrently or with partial concurrence.

Example 1. A computer system 100 comprising processing circuitry 110 configured to: during control, by the processing circuitry 110, of an electrical connection between a battery pack 200 and a traction system 12 of a vehicle 10 at a first switching frequency 351 of a set of predetermined switching frequencies 350, synchronously obtain a first cell voltage 321 and a first cell current 331 of a battery cell 210 of the battery pack 200; and provide the first cell voltage 321, the first cell current 331 and the first switching frequency 351 for diagnostic of the battery cell 210.

Example 2. The computer system 100 of example 1, wherein the processing circuitry 110 is further configured to: during control, by the processing circuitry 110, of an electrical connection between a battery pack 200 and a traction system 12 of a vehicle 10 at each additional switching frequency 353 of the set of predetermined switching frequencies 350, for each additional switching frequency 353, synchronously obtain an additional cell voltage 322 and an additional cell current 332 of a battery cell 210 of the battery pack 200; and provide the additional cell voltages 322, the additional cell currents 332 and their associated additional switching frequencies 353 for diagnostic of the battery cell 210.

Example 3. The computer system 100 of example 1 or 2, wherein the set of predetermined switching frequencies 350 first switching frequency 351 comprise one or more frequencies between 0.1 Hz to 10 KHz.

Example 4. The computer system 100 of any one of examples 1 to 3, wherein the processing circuitry 110 is further configured to: control the electrical connection between the battery pack 200 and the traction system 12 by controlling pre-charge transistor circuitry 203 of the battery pack 200.

Example 5. The computer system 100 of example 4, wherein the processing circuitry 110 is further configured to, prior to obtaining the cell voltages 321, 322 and cell currents 331, 332: control the traction system 12 to provide a short circuit to the battery pack 200; and control the pre-charge transistor circuitry 203 to limit currents from the battery pack 200.

Example 6. The computer system 100 of any one of examples 1 to 5, wherein the processing circuitry 110 is further configured to, prior to obtaining the cell voltages 321, 322 and cell currents 331, 332: control the traction system 12 to provide a discharge load to the battery pack 200.

Example 7. The computer system 100 of any one of examples 2 to 6, wherein the processing circuitry 110 is further configured to: obtain a plurality of first cell voltages 321, 322 as a series of first cell voltages 321, 322, a plurality of first cell currents 331 as a series of first cell currents 331, 332 synchronous to the series of first cell voltages 321, 322; obtain, for each additional frequency 353 of the set of predetermined switching frequencies 350, additional cell voltages 322 as a series of additional cell voltages 322 and a plurality of additional cell currents 332 as a series of additional cell currents 332 synchronous to the series of additional cell voltages 322, filter the series of first cell voltages 321 and the series of first cell currents 331 by a first filter 361, wherein the first filter 361 is tuned to the first switching frequency 351, and filter, for each additional frequency 353 of the set of predetermined switching frequencies 350, the series of additional cell voltage 322 and the series additional cell currents 332 by an additional filter 363, wherein the additional filter 363 is tuned to the associated additional switching frequency 353.

Example 8. The computer system 100 of example 7, wherein the first filter 361 and the additional filters 363 are the same tunable filter 360 and the processing circuitry 110 is further configured to tune the tunable filter 360 based on the switching frequency 351, 353.

Example 9. The computer system 100 of any one of examples 1 to 8, wherein the processing circuitry 110 is further configured to: process the first cell voltage 321 and the first cell current 331 to provide a first frequency internal resistance of the battery cell 210, and provide the first frequency internal resistance for diagnostic of the battery cell 210.

Example 10. The computer system 100 of any one of examples 1 to 9, wherein the processing circuitry 110 is further configured to: diagnose the battery pack 200 based on the obtained cell voltage/s 321, 322, the obtained cell current/s 331, 332 and their associated switching frequency/ies 351, 353, preferably by determining current state of health, SOH, of the battery pack 200 and compare the current SOH to a previous SOH of the battery pack 200.

Example 11. The computer system 100 of any one of examples 1 to 10, wherein the processing circuitry 110 is further configured to: control operation of the battery pack 200 based on the obtained cell voltage/s 321, 322, the obtained cell current/s 331, 332 and their associated switching frequency/ies 351, 353.

Example 12. The computer system 100 of example 1, wherein the processing circuitry 110 is further configured to: during control, by the processing circuitry 110, of an electrical connection between a battery pack 200 and a traction system 12 of a vehicle 10 at each additional switching frequency 353 of the set of predetermined switching frequencies 350, for each additional switching frequency 353, synchronously obtain an additional cell voltage 322 and an additional cell current 332 of a battery cell 210 of the battery pack 200; and provide the additional cell voltages 322, the additional cell currents 332 and their associated additional switching frequencies 353 for diagnostic of the battery cell 210; wherein the set of predetermined switching frequencies 350 first switching frequency 351 comprise one or more frequencies between 0.1 Hz to 10 kHz; wherein the processing circuitry 110 is further configured to: control the electrical connection between the battery pack 200 and the traction system 12 by controlling pre-charge transistor circuitry 203 of the battery pack 200; wherein the processing circuitry 110 is further configured to, prior to obtaining the cell voltages 321, 322 and cell currents 331, 332: control the traction system 12 to provide a short circuit to the battery pack 200; and control the pre-charge transistor circuitry 203 to limit currents from the battery pack 200; wherein the processing circuitry 110 is further configured to, prior to obtaining the cell voltages 321, 322 and cell currents 331, 332: control the traction system 12 to provide a discharge load to the battery pack 200; wherein the processing circuitry 110 is further configured to: obtain a plurality of first cell voltages 321, 322 as a series of first cell voltages 321, 322, a plurality of first cell currents 331 as a series of first cell currents 331, 332 synchronous to the series of first cell voltages 321, 322; obtain, for each additional frequency 353 of the set of predetermined switching frequencies 350, additional cell voltages 322 as a series of additional cell voltages 322 and a plurality of additional cell currents 332 as a series of additional cell currents 332 synchronous to the series of additional cell voltages 322, filter the series of first cell voltages 321 and the series of first cell currents 331 by a first filter 361, wherein the first filter 361 is tuned to the first switching frequency 351, and filter, for each additional frequency 353 of the set of predetermined switching frequencies 350, the series of additional cell voltage 322 and the series additional cell currents 332 by an additional filter 363, wherein the additional filter 363 is tuned to the associated additional switching frequency 353; wherein the first filter 361 and the additional filters 363 are the same tunable filter 360 and the processing circuitry 110 is further configured to tune the tunable filter 360 based on the switching frequency 351, 353; wherein the processing circuitry 110 is further configured to: process the first cell voltage 321 and the first cell current 331 to provide a first frequency internal resistance of the battery cell 210, and provide the first frequency internal resistance for diagnostic of the battery cell 210; wherein the processing circuitry 110 is further configured to: diagnose the battery pack 200 based on the obtained cell voltage/s 321, 322, the obtained cell current/s 331, 332 and their associated switching frequency/ies 351, 353, preferably by determining current state of health, SOH, of the battery pack 200 and compare the current SOH to a previous SOH of the battery pack 200; wherein the processing circuitry 110 is further configured to: control operation of the battery pack 200 based on the obtained cell voltage/s 321, 322, the obtained cell current/s 331, 332 and their associated switching frequency/ies 351, 353.

Example 13. An energy storage system 500 comprising at least one battery pack 200, at least one controllable connection 205 between the at least one battery pack 200 and a load 12 and the computer system 100 of any one of examples 1 to 12 operatively connected to the controllable connection 205.

Example 14. A vehicle 10, comprising a battery pack 200, a traction system 12 and the energy storage system of example 13.

Example 15. The vehicle 10 of example 14, wherein the vehicle is a heavy-duty vehicle 10.

Example 16. A computer implemented method 400 comprising: controlling 410, by processing circuitry 110 of a computer system 100, an electrical connection between a battery pack 200 and a traction system 12 of a vehicle 10 at a first switching frequency 351 of a set of predetermined switching frequencies 350, during control of the electrical connection, synchronously obtaining 420, by the processing circuitry 110 of the computer system 100, a first cell voltage 321 and a first cell current 331 of a battery cell 210 of the battery pack 200; and providing 430, by the processing circuitry 110 of the computer system 100, the first cell voltage 321, the first cell current 331 and the first switching frequency 351 for diagnostic of the battery cell 210.

Example 17. The computer implemented method 400 of example 16, further comprising: controlling 410, by the processing circuitry 110 of the computer system 100, the electrical connection between the battery pack 200 and the traction system 12 of the vehicle 10 at each additional switching frequency 353 of the set of predetermined switching frequencies 350; and during control of the electrical connection, for each additional switching frequency 353, synchronously obtaining 420, by the processing circuitry 110 of the computer system 100, an additional cell voltage 322 and an additional cell current 332 of a battery cell 210 of the battery pack 200; and providing 430, by the processing circuitry 110 of the computer system 100, the additional cell voltages 322, the additional cell currents 332 and their associated additional switching frequencies 353 for diagnostic of the battery cell 210.

Example 18. The computer implemented method 400 of example 16 or 17, wherein the set of predetermined switching frequencies 350 comprise one or more frequencies between 0.1 Hz to 10 KHz.

Example 19. The computer implemented method 400 of any one of examples 16 to 18 further comprising: controlling 410, by the processing circuitry 110 of the computer system 100, the electrical connection between the battery pack 200 and the traction system 12 by controlling pre-charge transistor circuitry 203 of the battery pack 200.

Example 20. The computer implemented method 400 of example 19, further comprising, prior to obtaining 420 the cell voltages 321, 322 and cell currents 331, 332: controlling, by the processing circuitry 110 of the computer system 100, the traction system 12 to provide a short circuit to the battery pack 200; and controlling, by the processing circuitry 110 of the computer system 100, the pre-charge transistor circuitry 203 to limit currents from the battery pack 200.

Example 21. The computer implemented method 400 of any one of examples 16 to 20 further comprising, prior to obtaining 420 the cell voltages 321, 322 and cell currents 331, 332: controlling, by the processing circuitry 110 of the computer system 100, the traction system 12 to provide a discharge load to the battery pack 200.

Example 22. The computer implemented method 400 of any one of examples 17 to 21 further comprising: obtaining 420, by the processing circuitry 110 of the computer system 100, a plurality of first cell voltages 321, 322 as a series of first cell voltages 321, 322, a plurality of first cell currents 331 as a series of first cell currents 331, 332 synchronous to the series of first cell voltages 321, 322; obtaining 420, by the processing circuitry 110 of the computer system 100, for each additional frequency 353 of the set of predetermined switching frequencies 350, additional cell voltages 322 as a series of additional cell voltages 322 and a plurality of additional cell currents 332 as a series of additional cell currents 332 synchronous to the series of additional cell voltages 322, filtering, by the processing circuitry 110 of the computer system 100, the series of first cell voltages 321 and the series of first cell currents 331 by a first filter 361, wherein the first filter 361 is tuned to the first switching frequency 351, and filtering, by the processing circuitry 110 of the computer system 100, for each additional frequency 353 of the set of predetermined switching frequencies 350, the series of additional cell voltage 322 and the series additional cell currents 332 by an additional filter 363, wherein the additional filter 363 is tuned to the associated additional switching frequency 353.

Example 23. The computer implemented method 400 of example 22, wherein the first filter 361 and the additional filters 363 are the same tunable filter 360 and the method 400 further comprises: tuning, by the processing circuitry 110 of the computer system 100, the tunable filter 360 based on the switching frequency 351, 353.

Example 24. The computer implemented method 400 of any one of examples 17 to 23 further comprising: processing, by the processing circuitry 110 of the computer system 100, the first cell voltage 321 and the first cell current 331 to provide a first frequency internal resistance of the battery cell 210, and providing 430, by the processing circuitry 110 of the computer system 100, the first frequency internal resistance for diagnostic of the battery cell 210.

Example 25. The computer implemented method 400 of any one of examples 16 to 24 further comprising: diagnosing, by the processing circuitry 110 of the computer system 100, the battery pack 200 based on the obtained cell voltage/s 321, 322, the obtained cell current/s 331, 332 and their associated switching frequency/ies 351, 353, preferably by determining current state of health, SOH, of the battery pack 200 and compare the current SOH to a previous SOH of the battery pack 200.

Example 26. The computer implemented method 400 of any one of examples 16 to 25 further comprising: controlling 410, by the processing circuitry 110 of the computer system 100, operation of the battery pack 200 based on the obtained cell voltage/s 321, 322, the obtained cell current/s 331, 332 and their associated switching frequency/ies 351, 353.

Example 27. A computer program product comprising program code for performing, when executed by the processing circuitry, the computer implemented method 400 of any one of examples 16 to 26.

Example 28. A non-transitory computer-readable storage medium comprising instructions, which when executed by the processing circuitry, cause the processing circuitry to perform the computer implemented method 400 of any one of examples 16 to 26.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. As used herein, the term “and/or” includes any and all combinations of one or more of the associated listed items. It will be further understood that the terms “comprises,” “comprising,” “includes,” and/or “including” when used herein specify the presence of stated features, integers, actions, steps, operations, elements, and/or components, but do not preclude the presence or addition of one or more other features, integers, actions, steps, operations, elements, components, and/or groups thereof.

It will be understood that, although the terms first, second, etc., may be used herein to describe various elements, these elements should not be limited by these terms. These terms are only used to distinguish one element from another. For example, a first element could be termed a second element, and, similarly, a second element could be termed a first element without departing from the scope of the present disclosure.

Relative terms such as “below” or “above” or “upper” or “lower” or “horizontal” or “vertical” may be used herein to describe a relationship of one element to another element as illustrated in the Figures. It will be understood that these terms and those discussed above are intended to encompass different orientations of the device in addition to the orientation depicted in the Figures. It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present.

Unless otherwise defined, all terms (including technical and scientific terms) used herein have the same meaning as commonly understood by one of ordinary skill in the art to which this disclosure belongs. It will be further understood that terms used herein should be interpreted as having a meaning consistent with their meaning in the context of this specification and the relevant art and will not be interpreted in an idealized or overly formal sense unless expressly so defined herein.

It is to be understood that the present disclosure is not limited to the aspects described above and illustrated in the drawings; rather, the skilled person will recognize that many changes and modifications may be made within the scope of the present disclosure and appended claims. In the drawings and specification, there have been disclosed aspects for purposes of illustration only and not for purposes of limitation, the scope of the disclosure being set forth in the following claims.

What is claimed is:

1. A computer system comprising processing circuitry configured to:
during control, by the processing circuitry, of an electrical connection between a battery pack and a traction system of a vehicle at a first switching frequency of a set of predetermined switching frequencies, synchronously obtain a first cell voltage and a first cell current of a battery cell of the battery pack; and
provide the first cell voltage, the first cell current and the first switching frequency for diagnostic of the battery cell.

2. The computer system of claim 1, wherein the processing circuitry is further configured to:
during control, by the processing circuitry, of an electrical connection between a battery pack and a traction system of a vehicle at each additional switching frequency of the set of predetermined switching frequencies, for each additional switching frequency, synchronously obtain an additional cell voltage and an additional cell current of a battery cell of the battery pack; and
provide the additional cell voltages, the additional cell currents and their associated additional switching frequencies for diagnostic of the battery cell.

3. The computer system of claim 1, wherein the set of predetermined switching frequencies comprise one or more frequencies between 0.1 Hz to 10 KHz.

4. The computer system of claim 1, wherein the processing circuitry is further configured to:
control the electrical connection between the battery pack and the traction system by controlling pre-charge transistor circuitry of the battery pack.

5. The computer system of claim 4, wherein the processing circuitry is further configured to, prior to obtaining the cell voltages and cell currents:
control the traction system to provide a short circuit to the battery pack; and
control the pre-charge transistor circuitry to limit currents from the battery pack.

6. The computer system of claim 1, wherein the processing circuitry is further configured to:
prior to obtaining the cell voltages and cell currents: control the traction system to provide a discharge load to the battery pack.

7. The computer system of claim 2, wherein the processing circuitry is further configured to:
obtain a plurality of first cell voltages as a series of first cell voltages, a plurality of first cell currents as a series of first cell currents synchronous to the series of first cell voltages;
obtain, for each additional frequency of the set of predetermined switching frequencies, additional cell voltages as a series of additional cell voltages and a plurality of additional cell currents as a series of additional cell currents synchronous to the series of additional cell voltages,
filter the series of first cell voltages and the series of first cell currents by a first filter, wherein the first filter is tuned to the first switching frequency, and
filter, for each additional frequency of the set of predetermined switching frequencies, the series of additional cell voltages and the series additional cell currents by an additional filter, wherein the additional filter is tuned to the associated additional switching frequency.

8. The computer system of claim 7, wherein the first filter and the additional filters are the same tunable filter and the processing circuitry is further configured to tune the tunable filter based on the switching frequency.

9. The computer system of claim 1, wherein the processing circuitry is further configured to: process the first cell voltage and the first cell current to provide a first frequency internal resistance of the battery cell, and provide the first frequency internal resistance for diagnostic of the battery cell.

10. The computer system of claim 1, wherein the processing circuitry is further configured to:
diagnose the battery pack based on the obtained cell voltage/s, the obtained cell current/s and their associated switching frequency/ies, preferably by determining current state of health (“SOH”) of the battery pack and compare the current SOH to a previous SOH of the battery pack.

11. The computer system of claim 1, wherein the processing circuitry is further configured to:
control operation of the battery pack based on the obtained cell voltage/s, the obtained cell current/s and their associated switching frequency/ies.

12. The computer system of claim 1 wherein the processing circuitry is further configured to: during control, by the processing circuitry, of an electrical connection between a battery pack and a traction system of a vehicle at each additional switching frequency of the set of predetermined switching frequencies, for each additional switching frequency, synchronously obtain an additional cell voltage and an additional cell current of a battery cell of the battery pack; and provide the additional cell voltages, the additional cell currents and their associated additional switching frequencies for diagnostic of the battery cell; control the electrical connection between the battery pack and the traction system by controlling pre-charge transistor circuitry of the battery pack; control the traction system to provide a short circuit to the battery pack; and control the pre-charge transistor circuitry to limit currents from the battery pack; obtain a plurality of first cell voltages as a series of first cell voltages, a plurality of first cell currents as a series of first cell currents synchronous to the series of first cell voltages; obtain, for each additional frequency of the set of predetermined switching frequencies, additional cell voltages as a series of additional cell voltages and a plurality of additional cell currents as a series of additional cell currents synchronous to the series of additional cell voltages, filter the series of first cell voltages and the series of first cell currents by a first filter, wherein the first filter is tuned to the first switching frequency, and filter, for each additional frequency of the set of predetermined switching frequencies, the series of additional cell voltage and the series additional cell currents by an additional filter, wherein the additional filter is tuned to the associated additional switching frequency; diagnose the battery pack based on the obtained cell voltage/s, the obtained cell current/s and their associated switching frequency/ies, preferably by determining current state of health, SOH, of the battery pack and compare the current SOH to a previous SOH of the battery pack; control operation of the battery pack based on the obtained cell voltage/s, the obtained cell current/s and their associated switching frequency/ies; wherein the set of predetermined switching frequencies comprise one or more frequencies between 0.1 Hz to 10 kHz; and wherein the processing circuitry is further configured to: process the first cell voltage and the first cell current to provide a first frequency internal resistance of the battery cell, and provide the first frequency internal resistance for diagnostic of the battery cell.

13. An energy storage system comprising at least one battery pack, at least one controllable connection between the at least one battery pack and a load and the computer system of claim 1 operatively connected to the controllable connection.

14. A vehicle, a traction system and the energy storage system of claim 13 connected to the traction system.

15. The vehicle of claim 14, wherein the vehicle is a heavy-duty vehicle.

16. A computer implemented method comprising:
controlling, by processing circuitry of a computer system, an electrical connection between a battery pack and a traction system of a vehicle at a first switching frequency of a set of predetermined switching frequencies,
during control of the electrical connection, synchronously obtaining, by the processing circuitry of the computer system, a first cell voltage and a first cell current of a battery cell of the battery pack; and
providing, by the processing circuitry of the computer system, the first cell voltage, the first cell current and the first switching frequency for diagnostic of the battery cell.

17. The computer implemented method of claim 16, further comprising:
controlling, by the processing circuitry of the computer system, the electrical connection between the battery pack and the traction system of the vehicle at each additional switching frequency of the set of predetermined switching frequencies; and
during control of the electrical connection, for each additional switching frequency, synchronously obtaining, by the processing circuitry of the computer system, an additional cell voltage and an additional cell current of a battery cell of the battery pack; and
providing, by the processing circuitry of the computer system, the additional cell voltages, the additional cell currents and their associated additional switching frequencies for diagnostic of the battery cell.

18. The computer implemented method of claim 16, further comprising: controlling, by the processing circuitry of the computer system, the electrical connection between the battery pack and the traction system by controlling pre-charge transistor circuitry of the battery pack.

19. A computer program product comprising program code for performing, when executed by a processing circuitry, the computer implemented method of claim 16.

20. A non-transitory computer-readable storage medium comprising instructions, which when executed by a processing circuitry, cause the processing circuitry to perform the computer implemented method of claim 16.
